(19) United States
(12) Patent Application Publication
(10) Pub. No.: US 2014/0159764 A1
(43) Pub. Date: Jun. 12, 2014

(54) SYSTEMS AND METHODS FOR FRACTURE DETECTION IN AN INTEGRATED CIRCUIT

(71) Applicant: APPLE INC., Cupertino, CA (US)

(72) Inventors: Ahmad Al-Dahle, Santa Clara, CA (US); Joshua G. Wurzel, Sunnyvale, CA (US); Yafei Bi, Palo Alto, CA (US)

(73) Assignee: APPLE INC., Cupertino, CA (US)

(21) Appl. No.: 13/712,628

(22) Filed: Dec. 12, 2012

(51) Int. Cl. G01R 31/26

(52) U.S. Cl. CPC G01R 31/2607
USPC 324/762.01

(57) ABSTRACT

Systems, methods, and devices are provided to identify the occurrence, location, and/or severity of a fracture within an integrated circuit, even when the integrated circuit is not accessible to external inspection. One such method includes obtaining a measurement of a property of the integrated circuit through at least one contact of the integrated circuit. The measurement may include a resistance of a resistive pattern in the integrated circuit or a measurement of current-voltage behavior of a power supply of the integrated circuit. The measurement of the property may be compared to an expected baseline property. Based at least in part on this comparison, whether a fracture of the integrated circuit has occurred and a location of the fracture in the integrated circuit may be determined.

### BACKGROUND

This disclosure relates to detecting a fracture in an integrated circuit.

This section is intended to introduce the reader to various aspects of art that may be related to various aspects of the present techniques, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

Integrated circuits are ubiquitous to modern electronic devices. Processors, memory, electronic display drivers, and many other components of modern electronic devices are formed as integrated circuits. As a result, a fracture of an integrated circuit may result in device malfunction or failure. When a fracture occurs in an externally accessible integrated circuit—that is, one that can be visually inspected and/or is otherwise accessible for testing—technicians may be able to identify the severity and/or location of the fracture. This information may enable improved designs or manufacturing processes that reduce the likelihood of fracture.

Although identifying the location and severity of integrated circuit fractures may be highly valuable, existing techniques tend to rely on external inspection. Not all integrated circuits of a larger electronic device, however, may be externally accessible. Electronic display driver circuitry, for example, is commonly disposed as a chip-on-glass (COG) circuit that is laminated within the electronic display. Integrated circuits such as these may be inaccessible to external inspection. As such, the location or severity of fractures occurring in these circuits may not be possible to identify using existing techniques.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

Embodiments relate systems, methods, and devices to identify the occurrence, location, and/or severity of a fracture within an integrated circuit, even when the integrated circuit is not accessible to external inspection. One such method includes obtaining a measurement of a property of the integrated circuit through at least one contact of the integrated circuit. The measurement may include a resistance of a resistive pattern in the integrated circuit or a measurement of current-voltage behavior of a power supply of the integrated circuit. The measurement of the property may be compared to an expected baseline property. Based at least in part on this comparison, whether a fracture of the integrated circuit has occurred and a location of the fracture in the integrated circuit may be determined.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings in which:

FIG. 1 is a block diagram of an electronic device having a display with display driver fracture detection circuitry, in accordance with an embodiment;

FIG. 2 is a perspective view of the electronic device of FIG. 1 in the form of a notebook computer, in accordance with an embodiment;

FIG. 3 is a front view of the electronic device of FIG. 1 in the form of a handheld device, in accordance with an embodiment;

FIG. 4 is a schematic block diagram of a system to detect fractures in display driver circuitry on the display, in accordance with an embodiment;

FIG. 5 is a perspective view of the display driver circuitry, in accordance with an embodiment;

FIG. 6 is a cross-sectional view of the display driver circuitry along cut lines 6-6 of FIG. 5, in accordance with an embodiment;

FIG. 7 is an example of a current-voltage (I-V) curve relating to a p-n junction in the display driver circuitry, in accordance with an embodiment;

FIG. 8 is a flowchart of a method to detect the occurrence of a fracture in the display driver by comparing I-V curves, in accordance with an embodiment;

FIG. 9 is a flowchart of a method to detect a location of a fracture by comparing I-V curves, in accordance with an embodiment;

FIGS. 10-13 are cross-sectional views of fractures in different regions of the display driver circuitry, in accordance with embodiments;

FIG. 14 is a schematic block diagram of a system to detect a fracture in the display driver circuitry by measuring resistive traces disposed in the display driver, in accordance with an embodiment;

FIG. 15 is a circuit diagram of driver fracture detection circuitry viewed schematically from above the display driver, in accordance with an embodiment;

FIG. 16 is a flowchart of a method to detect a fracture in the display driver by measuring a resistance of resistive traces formed in the display driver, in accordance with an embodiment;

FIGS. 17-20 are examples of fractures in different regions of the display driver in relation to the resistive traces of FIG. 15, in accordance with embodiments;

FIG. 21 is a system to detect a fracture in a flexible circuit connected to the display driver, in accordance with an embodiment;

FIG. 22 is a flowchart of a method to detect a fracture in a display driver during the manufacture of the electronic device of FIG. 1, in accordance with an embodiment;

FIG. 23 is a flowchart of a method to detect the occurrence, location, and/or severity of a fracture in the display driver circuitry while the electronic device is being used, in accordance with an embodiment; and

FIG. 24 is a flowchart of a method to ascertain the occurrence, location, and/or severity of a fracture in a display driver when a damaged electronic device is brought to a repair facility, in accordance with an embodiment.

### DETAILED DESCRIPTION

One or more specific embodiments of the present disclosure will be described below. These described embodiments are only examples of the presently disclosed techniques. Additionally, in an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but may nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

This disclosure relates to identifying the severity and/or location of a fracture or microfracture of an integrated circuit. As used here, the terms “fracture” and “microfracture” refer to cracks or breakages that impede the operation of the integrated circuit in some way. For instance, a fracture or microfracture may cause display driver circuitry of a display not to properly drive an electronic display. This disclosure will provide systems, methods, and devices with which fractures or microfractures in an integrated circuit can be identified. These systems, methods, and devices may identify the fractures or microfractures even when the integrated circuit is inaccessible to external inspection (e.g., is laminated or stacked within other electronic components), as often may be the case of display driver circuitry. As such, the discussion below will use display driver circuitry by way of example. Still, it should be appreciated that the systems, methods, and devices of this disclosure may be used to identify the severity and/or location of fractures in any other suitable types of integrated circuits. Such integrated circuits may include those that are not accessible to external inspection, as well as those that are.

As mentioned above, one particular form of integrated circuit that may benefit from this disclosure may be chip-on-glass (COG) driver circuitry installed on an electronic display. A fracture or microfracture in the driver of the electronic display could cause the display to malfunction or fail. Often, such fractures are caused in part by the design of the display or of the electronic device where the display is installed. For instance, the display driver may be located too near to another component of the electronic device. Too much pressure or torsion on the electronic device could cause the other component to impact the display driver. In other cases, fractures could be caused by defective manufacturing technique or assembly line. For example, one assembly line in particular could be applying too much pressure to the display of the electronic device when the display is being installed. In still other examples, the display driver may develop a fracture or microfracture when the electronic device is dropped or mishandled.

Fractures occurring within an integrated circuit may be identified in a variety of ways. In one example, the location of the fracture may be determined by the effect of the fracture on the power supply connections of the integrated circuit. Indeed, a fracture or microfracture in the display driver will affect the relationship between some power supply connections (e.g., 6 v, 1.8 v, and so forth) and a low voltage backplane (e.g., a VCPL backplane). The low voltage backplane may be supplied from a different location on the display driver from other power supply connections, and the low voltage backplane may relate to the other power supply connections through p-n junctions. When no fractures are present, each p-n junction may behave according to respective baseline I-V curves. When a fracture or microfracture occurs, however, the I-V curves of those connections affected by the fracture will change owing to the disruption in the integrated circuit. The I-V curves of the p-n junctions that are not disrupted by the fracture or microfracture, however, will remain the same. By detecting which of the I-V curves change, the general location of a fracture or microfracture in the integrated circuit may be detected.

In another example, resistors disposed within the integrated circuit may be used to generally identify where the location and/or severity of a fracture. A fracture may cause the resistance to vary in a manner dependent on the location and/or severity of the fracture. For example, a path with various resistors in parallel may be formed on the integrated circuit. A fracture occurring along a first segment of the paths may cut off some of the resistors in parallel from the path, thereby resulting in a first resistance of the path. If the fracture occurs along a different segment, a different number of the resistors may be cut off from the path, resulting in a second resistance of the path.

Determining the severity and/or the location of a fracture in an integrated circuit may enable designers to avoid future fractures. Knowing the location and/or severity of a fracture, for instance, may assist in a root cause analysis to improve device design or manufacturing. Moreover, determining where such a fracture or microfracture occurs in the display driver could be carried out strictly during the development of the electronic device (e.g., design and manufacturing) or could be implemented in electronic device publicly available to users. In the latter case, identifying the locations of fractures of devices that have been sold to users may enable the collection of fracture statistics over the population of electronic devices. In either case, knowledge of the location and/or severity of fractures may allow electronic device designers and manufacturers to improve device reliability and/or manufacturing yield.

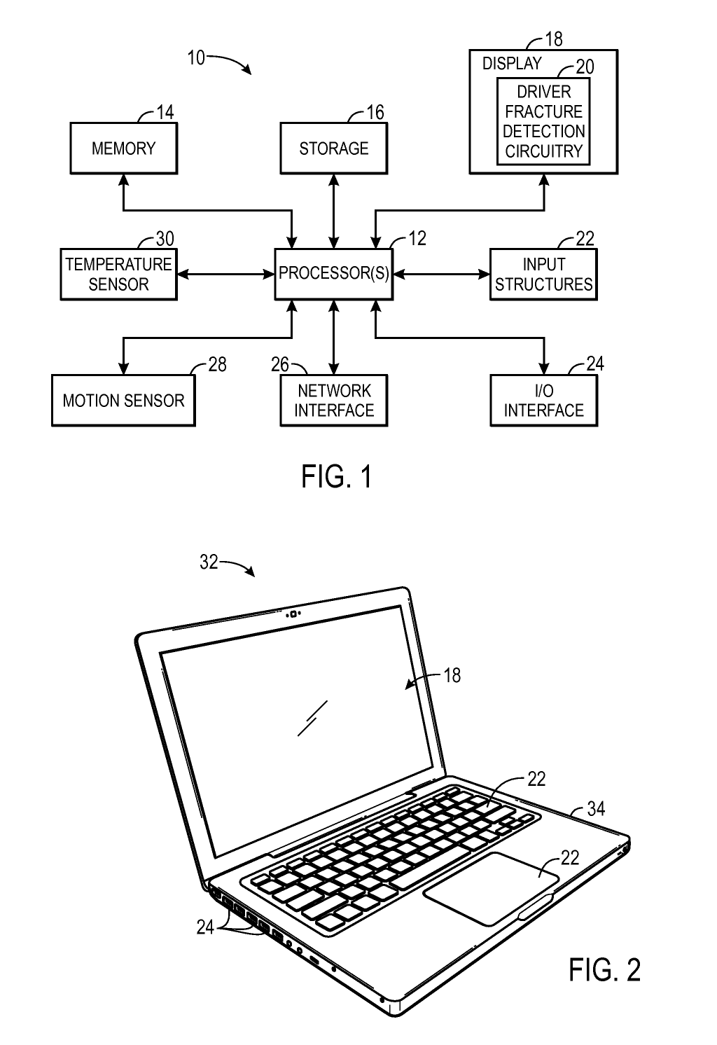

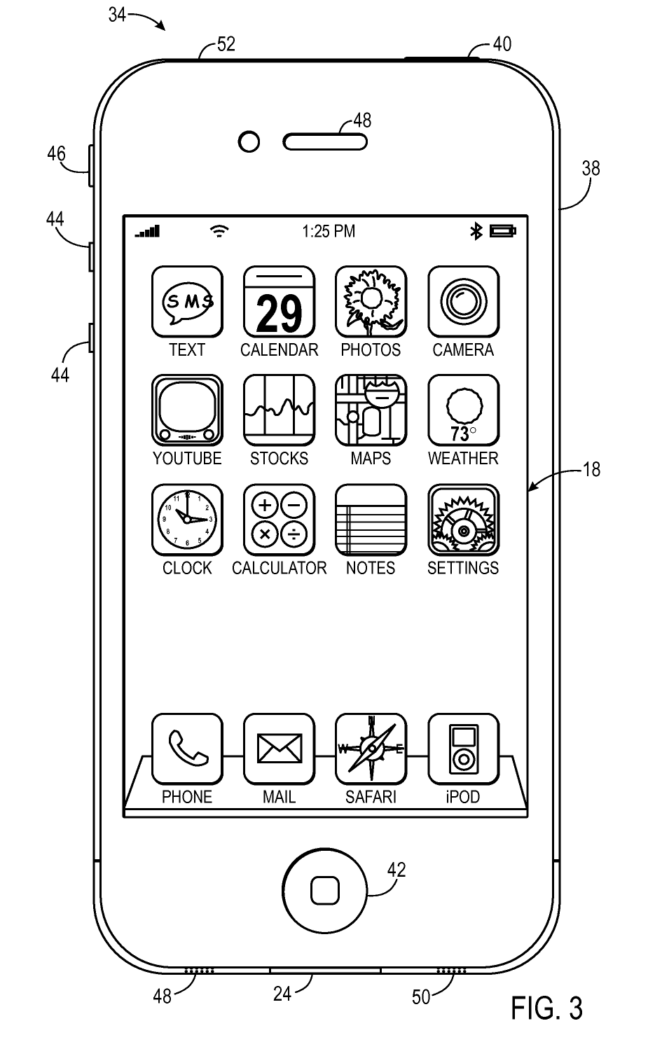

With the foregoing in mind, many suitable electronic devices may employ circuitry to identify fractures in integrated circuits (e.g., display driver circuitry of an electronic display). FIG. 1 is a block diagram depicting various components that may appear in such an electronic device. FIGS. 2 and 3 respectively illustrate perspective and front views of suitable electronic devices. Specifically, FIG. 2 illustrates a notebook computer and FIG. 3 illustrates a handheld electronic device.

Turning first to FIG. 1, one suitable electronic device 10 may include, among other things, one or more processor(s) 12, memory 14, nonvolatile storage 16, a display 18 having fracture detection circuitry 20, input structures 22, an input/output (I/O) interface 24, network interfaces 26, motion sensor(s) 28, and/or a temperature sensor 30. The various functional blocks shown in FIG. 1 may include hardware elements (including circuitry), software elements (including computer code stored on a computer-readable medium) or a combination of both hardware and software elements. It should be noted that FIG. 1 is merely one example of a particular implementation and is intended to illustrate the types of components that may be present in the electronic device 10.

In the electronic device 10 of FIG. 1, the processor(s) 12 and/or other data processing circuitry may be operably coupled with the memory 14 and the nonvolatile memory 16 to execute instructions. In one example, the processor(s) 12 may execute instructions to generate image data to be displayed on the display 18 or to identify fractures using the fracture detection circuitry 20. The display 18 may be a touch-screen liquid crystal display (LCD). In some embodiments, the electronic display 18 may be a Multi-Touch™ display that can detect user gestures of multiple simultaneous touches. The fracture detection circuitry 20 of the display 18 may identify the severity and/or location of fractures occurring in the driver circuitry of the display 18.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interfaces 26. The network interfaces 26 may include, for example, interfaces for a personal area network (PAN), such as a Bluetooth network, for a local area network (LAN), such as an 802.11x Wi-Fi network, and/or for a wide area network (WAN), such as a 3G or 4G cellular network. The motion sensor(s) 28 may detect the movement of the electronic device 10 and may represent, for example, a gyroscope (e.g., a six-axis gyroscope), an accelerometer, and/or a magnetometer. The temperature sensor 30 may detect extreme temperatures (e.g., high or low temperatures that may damage components of the electronic device 10).

The electronic device 10 may take the form of a computer or other suitable type of electronic device. Such computers may include computers that are generally portable (such as laptop, notebook, and tablet computers) as well as computers that are generally used in one place (such as conventional desktop computers, workstations, and servers). In certain embodiments, the electronic device 10 in the form of a computer may be a model of a MacBook®, MacBook® Pro, MacBook Air®, iMac®, Mac® mini, or Mac Pro® available from Apple Inc. In FIG. 2, the electronic device 10 takes the form of a notebook computer 32. The depicted notebook computer 32 may include a housing 34, a display 18, input structures 22, and ports of an I/O interface 24. In one embodiment, the input structures 22 (such as a keyboard and/or touchpad) may be used to interact with the computer 32, such as to start, control, or operate a GUI or applications running on computer 32. The display 18 may use the fracture detection circuitry 20 to identify the severity and/or location of fractures occurring in the display driver circuitry of the display 18.

In FIG. 3, the electronic device 10 is depicted as a handheld device 36. The handheld device 36 may represent, for example, a portable phone, a media player, a personal data organizer, or a handheld game platform, to name a few examples. By way of example, the handheld device 36 may be a model of an iPod® or iPhone® available from Apple Inc. of Cupertino, Calif. In other embodiments, the handheld device 36 may be a tablet-sized embodiment of the electronic device 10, which may be, for example, a model of an iPad® available from Apple Inc.

The handheld device 36 may include an enclosure 38 to protect interior components from physical damage and to shield them from electromagnetic interference. The enclosure 38 may surround the display 18. The I/O interfaces 24 may open through the enclosure 38 and may include, for example, a proprietary I/O port from Apple Inc. to connect to external devices. User input structures 40, 42, 44, and 46, in combination with the display 18, may allow a user to control the handheld device 36. For example, the input structure 40 may activate or deactivate the handheld device 36, the input structure 42 may navigate a user interface to a home screen, a user-configurable application screen, and/or activate a voice-recognition feature of the handheld device 36, the input structures 44 may provide volume control, and the input structure 46 may toggle between vibrate and ring modes. A microphone 48 may obtain a user's voice for various voice-related features, and a speaker 50 may enable audio playback and/or certain phone capabilities. A headphone input 52 may provide a connection to external speakers and/or headphones.

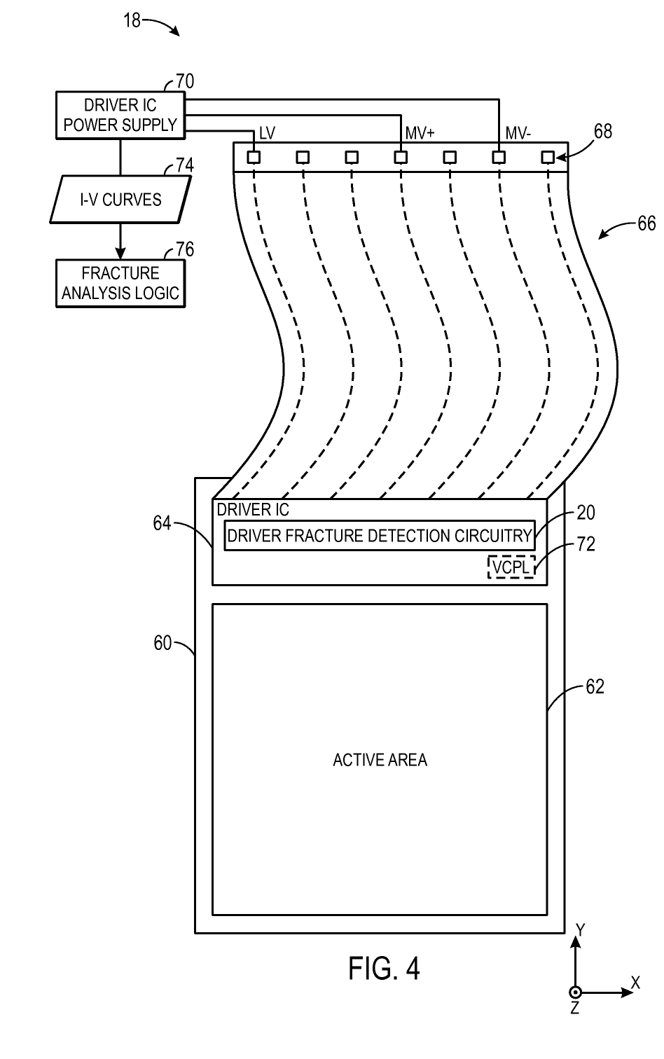

Regardless of the form of the electronic device 10, the electronic display 18 of the electronic device 10 may use the fracture detection circuitry 20 to allow the occurrence, location, and/or severity of a fracture to be detected. In an example shown in FIG. 4, the display 18 includes a display panel 60 with an active area 62 that is controlled by a display driver integrated circuit (IC) 64. The active area 62 may represent any suitable matrix of pixels that the display driver IC 64 controls. For instance, the active area 62 may represent a matrix of pixels of a liquid crystal display (LCD). In another example, the active area 62 may represent organic light emitting diodes (OLEDs). The display driver IC 64 may program the pixels of the active area 62 to display images on the display 18. Image data signals and some power supply signals may be sent to the display driver IC 64 over a flexible printed circuit, or flex, 66 having several channels accessible by flex connections 68. A coordinate system shown using x, y, and z coordinates in FIG. 4 will be used throughout the disclosure below.

A display driver IC power supply 70 may supply certain power supply signals. In the example of FIG. 4, these power supply signals include a low voltage (LV) (e.g., 1.8V), a positive medium voltage MV+ (e.g., 6V), and a negative medium voltage MV− (e.g., −6V). In other embodiments, the display driver IC power supply 70 may supply more or fewer power supply signals. In addition to the power supply signals from the display driver IC power supply 70 (e.g., LV, MV+, and MV−), the display driver IC 64 may receive a low voltage backplane (VCPL) 72 from a source other than the display driver IC power supply 70. In other embodiments, the display driver IC power supply 70 may also supply the VCPL 72.

Using the power supply signals and other data signals provided over the flex 66, the driver IC 64 may program the pixels of the active area 62. Under certain conditions, however, the driver IC 64 may develop a fracture (e.g., due to manufacturing defects or accidentally being dropped). As a result, the display driver IC 64 may fail to operate properly. Thus, the driver IC 64 may benefit from fracture detection circuitry 20, which may detect the severity and/or location of the fracture. In some examples, the fracture detection circuitry 20 represents dedicated circuitry of the display driver IC 64 that specifically detects fractures. In other examples, however, the fracture detection circuitry 20 may represent circuitry that commonly appears in display driver IC circuits, but which may be employed according to techniques disclosed below to determine the location of a fracture.

In the example of FIG. 4, the fracture detection circuitry 20 represents circuitry the latter case mentioned above. Specifically, the fracture detection circuitry 20 represents the power supply circuitry, the behavior of which may change when fractures are present. Namely, the location of fractures in the display driver IC 64 may be ascertained by comparing current-voltage (I-V) curves relating the power supply signals LV, MV+, and/or MV− to the VCPL 72 of power supply. Specifically, the display driver IC power supply 70 may occasionally determine such I-V curves 74. Fracture analysis logic 76 may determine, using these I-V curves 74, whether and/or where a fracture has occurred in the display driver IC 64. The fracture analysis logic 76 may represent, for example, hardware logic of the display 18 and/or software implemented by the processor(s) 12 or by a microcontroller of the display 18. Additionally or alternatively, the fracture analysis logic 76 may represent logic implemented by external computing circuitry used to test the display 18 during the manufacturing process. The manner in which the fracture analysis logic 76 may ascertain the occurrence and/or occurrence, location, and/or severity of a fracture of the display driver IC 64 will be discussed in greater detail below.

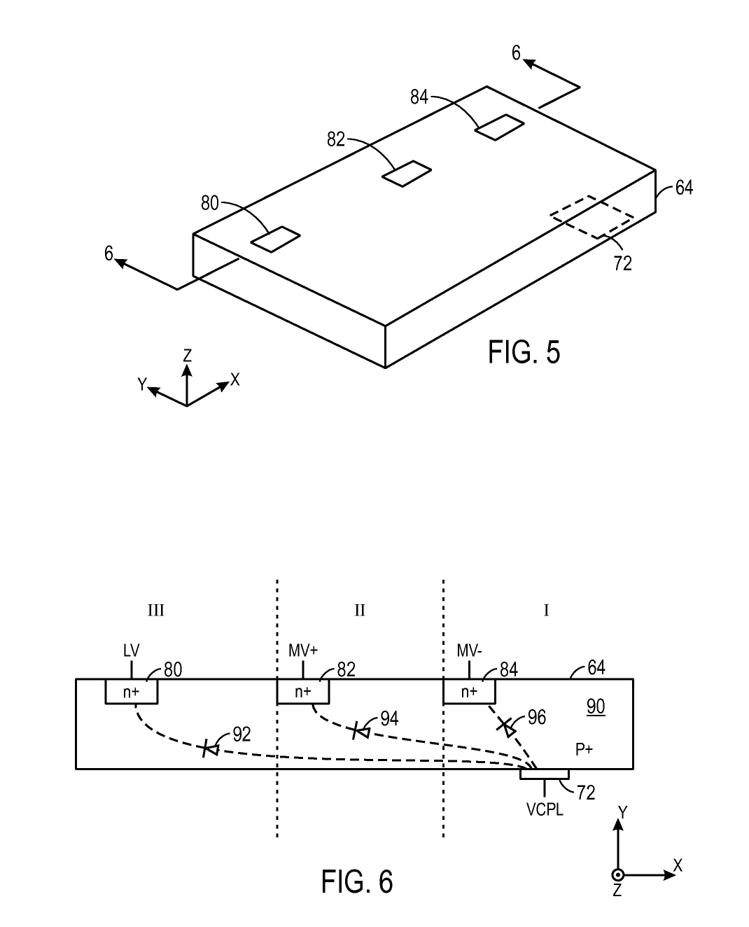

The display driver IC 64 is shown in perspective view in FIG. 5. Here, a spatial relationship between the VCPL 72 power supply and chip-on-glass (COG) pads 80, 82, and 84 can be seen. In the example of FIG. 5, the three spatial dimensions of the display driver IC 64 can be seen in relation to the x, y, and z coordinates that also appeared in FIG. 4. In the example of FIG. 5, the COG pad 80 corresponds to a connection to the LV power supply signal, the COG pad 82 corresponds to a connection to the MV+ power supply signal, and the COG pad 84 corresponds to the connection to the MV− power supply signal. As noted above, more or fewer power supply signals and COG pads may be used in the display driver IC 64. The COG pads 80, 82, and 84 are shown by way of example for ease of explanation.

FIG. 6 represents a cross-sectional view of the display driver IC at cut lines 6-6 of FIG. 5. As seen in FIG. 6, the COG pads 80, 82, and 84 may correspond to n+ doped wells in a p+ doped substrate. These n+ doped wells within the p+ doped substrate 90 may form p-n junctions 92, 94, and 96 with the VCPL 72. These p-n junctions 92, 94, and 96 may be visualized as diodes in FIG. 6. Each of the COG pads 80, 82, and 84 may be understood to correspond to a different region (e.g., I, II, or III) as shown in FIG. 6. Each region I, II, or III substantially includes a particular set of the p-n junctions 92, 94, and 96. Namely, region I includes all three p-n junctions 92, 94, and 96; region II includes two p-n junctions 92 and 94; and region III includes only the p-n junction 92. Monitoring changes in behavior of the p-n junctions 92, 94, and 96 thus may indicate whether a fracture has occurred in region I, II, and/or III.

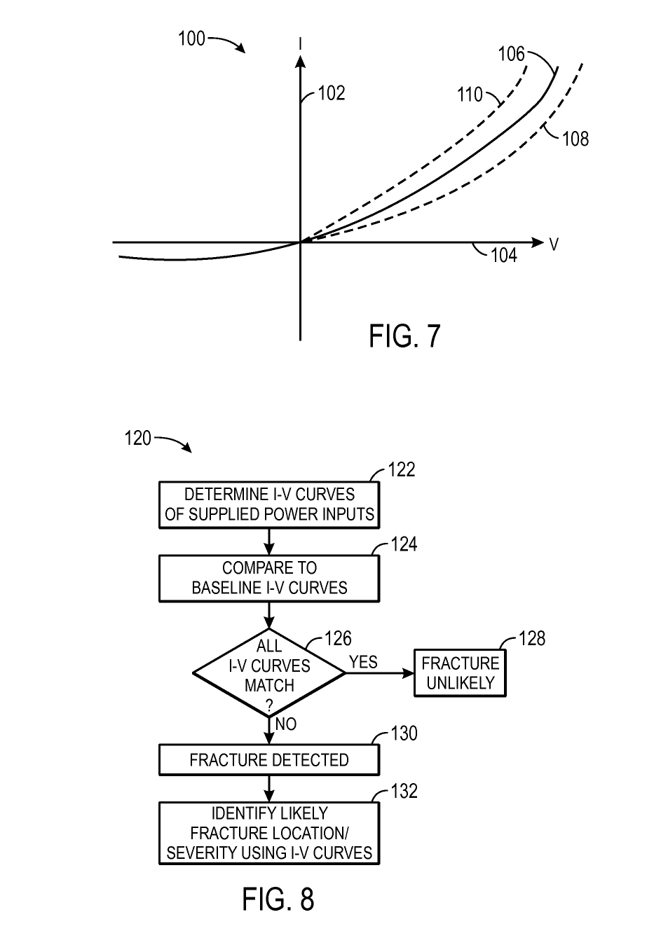

First, note that each of the p-n junctions 92, 94, and 96 may have a particular current-voltage (I-V) relationship. One example of such a current-voltage (I-V) relationship is shown as an I-V curve 100 of FIG. 7. In the I-V curve 100 of FIG. 7, an ordinate 102 represents a current I and an abscissa 104 represents a corresponding voltage V of one of the p-n junctions (e.g., the p-n junction 92). A baseline I-V curve 106 represents an I-V curve that, under normal operation, may vary within an expected range from between curves 108 and 110. If the baseline curve 106 falls outside the expected range between curves 108 and 110, this may imply that some defect, such as a fracture, has occurred in the display driver IC 64.

As such, the fracture analysis logic 76, which may be implemented as software running on the processor(s) 12 and/or hardware or firmware of any other suitable component of the electronic device 10, may identify fractures by comparing such I-V curves. In an example flowchart 120 of FIG. 8, the fracture analysis logic 76 first may determine the current actual I-V curves of the supplied power inputs as apparent to the driver IC power supply 70 (block 122). The fracture analysis logic 76 may compare the actual I-V curves 74 to expected baseline I-V curves 106 (block 124). When the actual I-V curves 74 match the expected baseline I-V curves 106 (decision block 126), a fracture may be unlikely (block 128). At the same time, if any of the I-V curves 74 do not match the respective expected baseline I-V curves 106 (decision block 126), a fracture may be understood to have been detected (block 130). In addition to identifying that a fracture has occurred at block 130, the fracture analysis logic 76 also may identify the location and/or the severity of the fracture using the I-V curves (block 132).

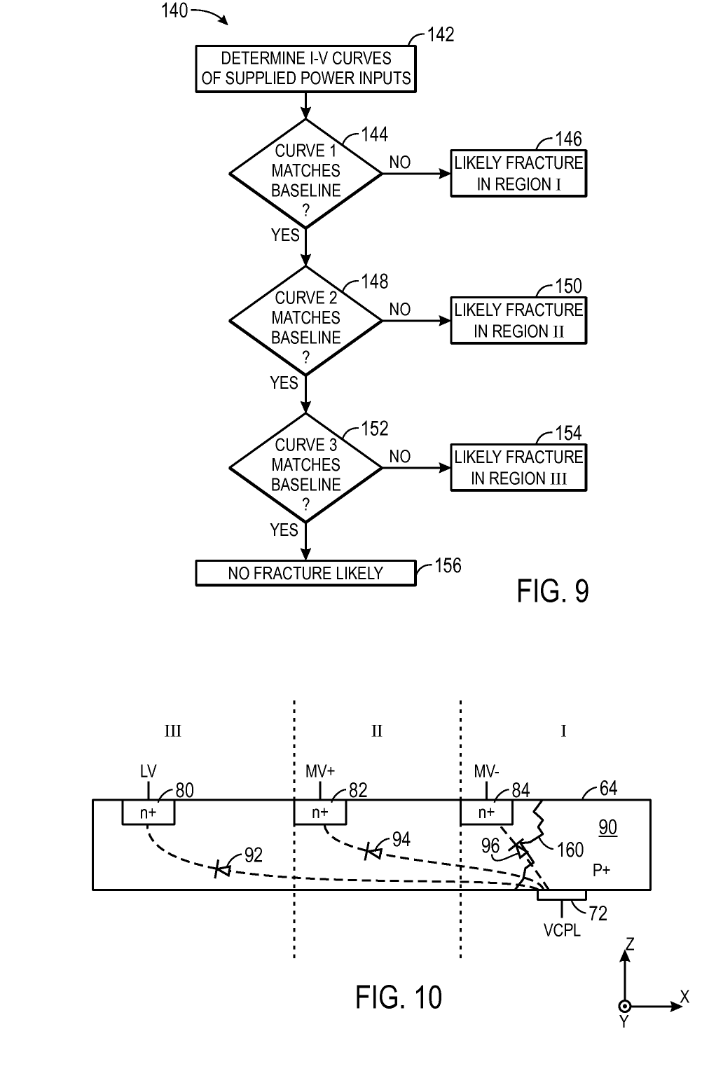

For example, as illustrated by a flowchart 140 of FIG. 9, the fracture analysis logic 76 may compare the actual I-V curves 74 to respective baseline I-V curves 106 to identify whether a fracture has occurred in a particular region (e.g., I, II, and/or III) of the display driver IC 64 (block 142). Specifically, if a first I-V curve corresponding to the p-n junction of the power supply input node 84 with respect to the VCPL input 72 does not substantially match a respective baseline I-V curve 106, a fracture may have occurred in region I of the display driver IC 64 (block 146). As used herein, the terms “match” or “substantially match” refer to whether the actual I-V curve 74 generally falls within the expected range of I-V curves (e.g., between curves 108 and 110) around the expected baseline I-V curve 106 during normal operation of the display driver IC 64. When the first I-V curve 74 relating the p-n junction between the power supply input node 84 and the VCPL input node 72 does substantially match its respective baseline (decision block 144), a fracture in region I may be unlikely, but may be possible in other regions. For example, if a second I-V curve 74 relating the power supply input node 82 to the VCPL input node 72 does not match a respective baseline (decision block 148), a fracture may likely have occurred in region II of the driver IC 64 (block 150). When the I-V curves 74 relating to the power supply input nodes 84 and 82 do substantially match their respective baseline I-V curves 106 (decision blocks 144 and 148), a fracture still may be possible in region III of the drive IC. Indeed, if a third I-V curve 74, relating the power supply input node 80 to the VCPL input node 72, does not match its respective baseline I-V curve (decision block 152), a fracture may be likely to have occurred in region III of the driver IC 64 (block 154). Otherwise, no fractures are likely to have occurred (block 156).

FIGS. 10, 11, and 12 represent examples of the failure modes of blocks 146, 150, and 154, respectively. FIGS. 10-12 represent cross-sectional views of the display driver IC 64 at cut lines 6-6 of FIG. 5. As such, the height (z-axis) and length (x-axis) of the driver IC 64 can be seen in FIGS. 10-12. In FIG. 10, a fracture 160 has occurred in region I of the display driver IC 64, representing a failure mode of block 146. Here, the fracture 160 separates the power supply input nodes 80, 82, and 84 from the VCPL input node 72. The fracture 160 thus interrupts the p-n junctions 92, 94, and 96. This accordingly alters the I-V characteristics of the power supply input nodes 80, 82, and 84.

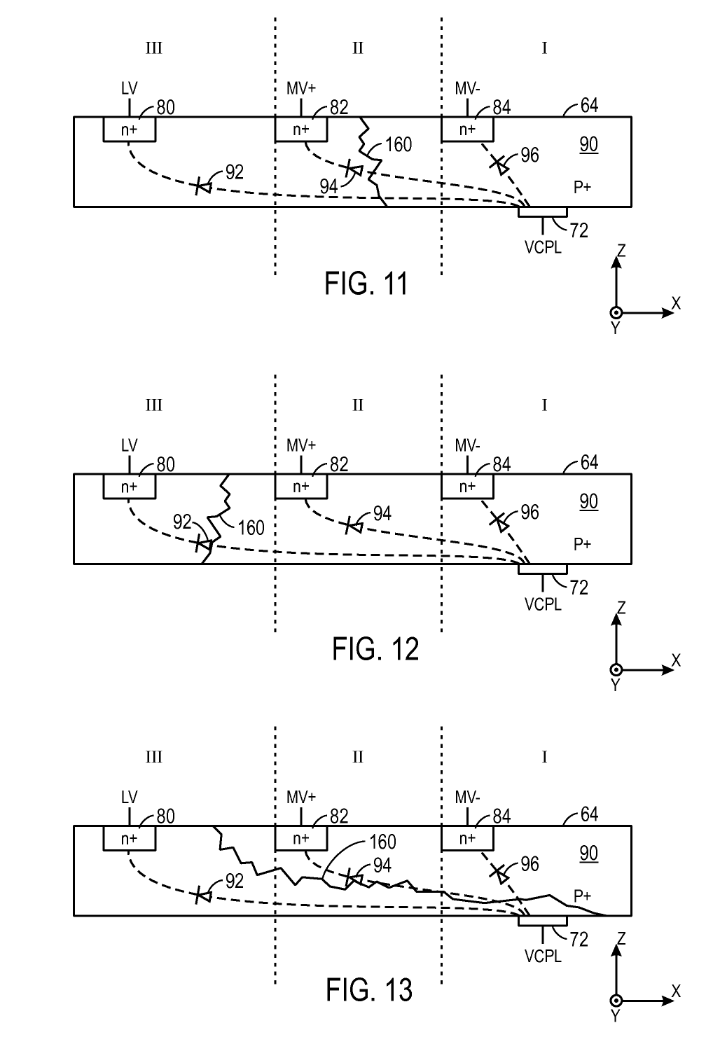

In contrast, when the fracture 160 occurs in region II as shown in FIG. 11, the fracture 160 separates only the power supply input nodes 80 and 82 from the VCPL input node 72. This interrupts the p-n junctions 92 and 94. The I-V characteristics of the power supply input nodes 80 and 82 may be altered accordingly, but the I-V characteristics of the power supply input node 84 may remain generally unchanged from its expected baseline I-V characteristics. FIG. 11 thus represents the failure mode of block 152 of the flowchart 140 of FIG. 9.

FIG. 12 represents the failure mode of block 154 of the flowchart 140. In FIG. 12, the fracture 160 appears in region III of the display driver IC 64. The fracture 160 only separates the power supply input node 80 from the VCPL input node 72. The power supply input nodes 82 and 84 are not disrupted and may have I-V curves 74 that may not have changed in relation to their respective baseline I-V curves 106.

Other failure modes are possible, as illustrated in FIG. 13. Like FIGS. 10-12, FIG. 13 is a cross-sectional view of the display driver IC 64 from cut lines 6-6 of FIG. 5. Thus, FIG. 13 presents a schematic view of the height (z-axis) and length (x-axis) of the display driver IC 64. In the example of FIG. 13, a fracture 160 is shown to have occurred in a way that crosses several regions. Still, the fracture 160 may be identified as occurring at least in regions I and II by ascertaining that the I-V curves 74 relating to the power supply input nodes 82 and 84 do not substantially match their respective baseline I-V curves 106, while the I-V curve 74 relating to the power supply input node 80 is closer to its respective baseline I-V curve 106. Still, as seen in FIG. 13, the fracture 160 extends into region III, though not directly traversing the p-n junction 92. The fracture 160 still may impact the behavior of the I-V curve 74 of the power supply input node 80 (e.g., moving the values nearer to the I-V curves 108 and/or 110). As such, the fracture analysis logic 76 may determine that the fracture 160 has occurred to the extent shown in FIG. 13 from the behavior of the I-V curves 74.

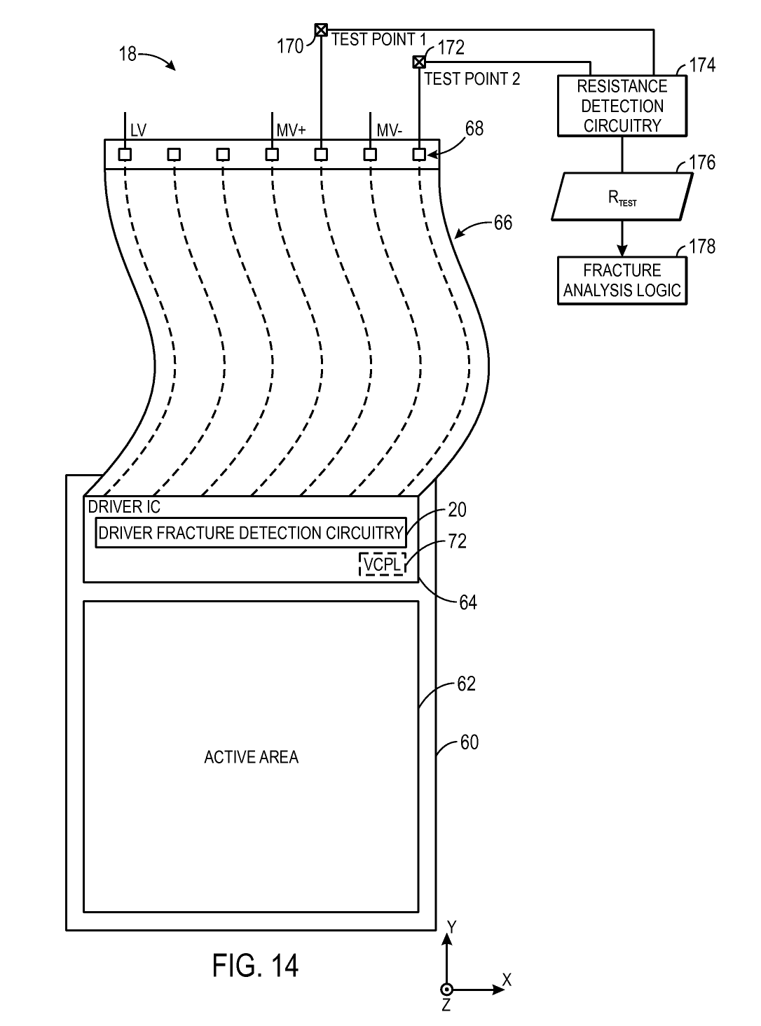

In the examples of FIGS. 4-12 discussed above, the occurrence, location, and/or severity of a fracture in an integrated circuit (e.g., the display driver IC 64) may be determined based on the I-V behavior of power supply inputs (e.g., 80, 82, and 84). Still, the fracture detection circuitry 20 may detect fractures in other ways. For example, the fracture detection circuitry 20 of the display driver IC 64 may employ certain resistive traces to indicate the occurrence of a fracture, as shown in FIG. 14. Specifically, the display 18 may include the display panel 60, the active area 62 of which may be controlled by the display driver IC 64. The fracture detection circuitry 20 may represent resistive traces that, when disrupted, will indicate the occurrence of a fracture through a change in electrical resistance. Test points 170 and 172 may connect to the resistive traces of the fracture detection circuitry 20 of FIG. 14. As seen in FIG. 14, the test points 170 and 172 may occupy flex connections 68 into the flex 66, thereby connecting to the display driver IC 64 through flex-on-glass (FOG) connections.

Through the test points 170 and 172, (“test point1” and “test point 2,” respectively) resistance detection circuitry 174 may obtain a test resistance 176, here shown as a resistance Rₜₑₛₜ. Fracture analysis logic 178 may receive a value of the Rₜₑₛₜ resistance 176 and determine based on the Rₜₑₛₜ resistance 176 whether a fracture has occurred. The value of the Rₜₑₛₜ resistance 176 may also indicate a likely location of the fracture within the display driver IC 64.

Before continuing further, it should be noted that the resistance detection circuitry 174 and the fracture analysis logic 178 may be implemented in the display 18 itself, in the electronic device 10 in which the electronic display 18 is installed, and/or in some external circuitry for testing the displays 18 during the manufacture of the display 18 and/or electronic device 10. The fracture analysis logic 178 may represent logic implemented as hardware and/or software in the manner of the fracture analysis logic 76. The Rₜₑₛₜ resistance 176 may be converted into a digital value by analog-to-digital converter (ADC), and the fracture analysis logic 178 may operate using a digital value of the Rₜₑₛₜ resistance 176.

One example of the fracture detection circuitry 20 that may be implemented in the display driver IC 64 appears in FIG. 15. In the example of FIG. 15, the resistive traces that include resistive elements R₁, R₂, R₃, R₄, R₅, R₆, R₇, and R₈. Other examples of the fracture detection circuitry 20 may include more or fewer resistive elements arranged in any suitable pattern. Indeed, the location of the resistive traces and the resistive elements are shown schematically in the example of FIG. 15. In an actual implementation, the resistive traces and the resistive elements may be located elsewhere. That is, the resistances R₁, R₂, R₃, R₄, R₅, R₆, R₇, and R₈, may be arranged in the pattern shown in FIG. 15 to generally define several fracture regions I, II, III, IV, and so forth. In this arrangement, fractures occurring in any of these particular regions I, II, III, or IV, may be detected based on the resistance identified between the test points 170 and 172. Moreover, the fracture detection circuitry 20 shown in FIG. 15 may indicate fractures in a substantially planar manner that divide the x-y plane of the display driver IC. In other example, however, the resistive traces of the fracture detection circuitry 20 may be vertically aligned, instead, such that fractures may be detected along the x-z or y-z plane, or a combination of these may be employed.

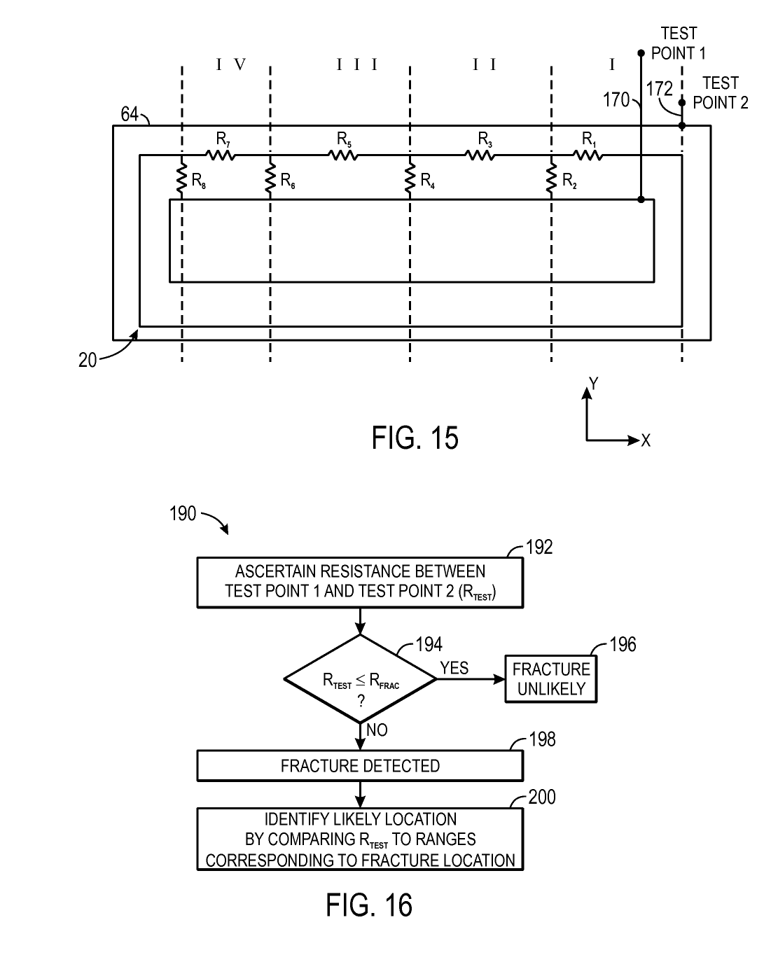

The fracture analysis logic 178 may determine the occurrence and/or location of a fracture according to a flowchart 190 shown in FIG. 16. The flowchart 190 may begin when the resistance Rₜₑₛₜ 176 between the test points 170 and 172 is determined (block 192). When the test resistance Rₜₑₛₜ 176 remains beneath some threshold resistance R_{frac} that represents a restriction in which a fracture is likely to have occurred (decision block 194), a fracture is unlikely to have occurred (block 196).

On the other hand, if the test resistance Rₜₑₛₜ 176 is greater than the fracture threshold resistance R_{frac} (decision block 194), a fracture may be indicated as having been detected (block 198). In addition, the fracture analysis logic 178 may determine the likely location of the fracture by comparing the test resistance Rₜₑₛₜ 176 to ranges of resistance that correspond to certain fracture locations (block 200).

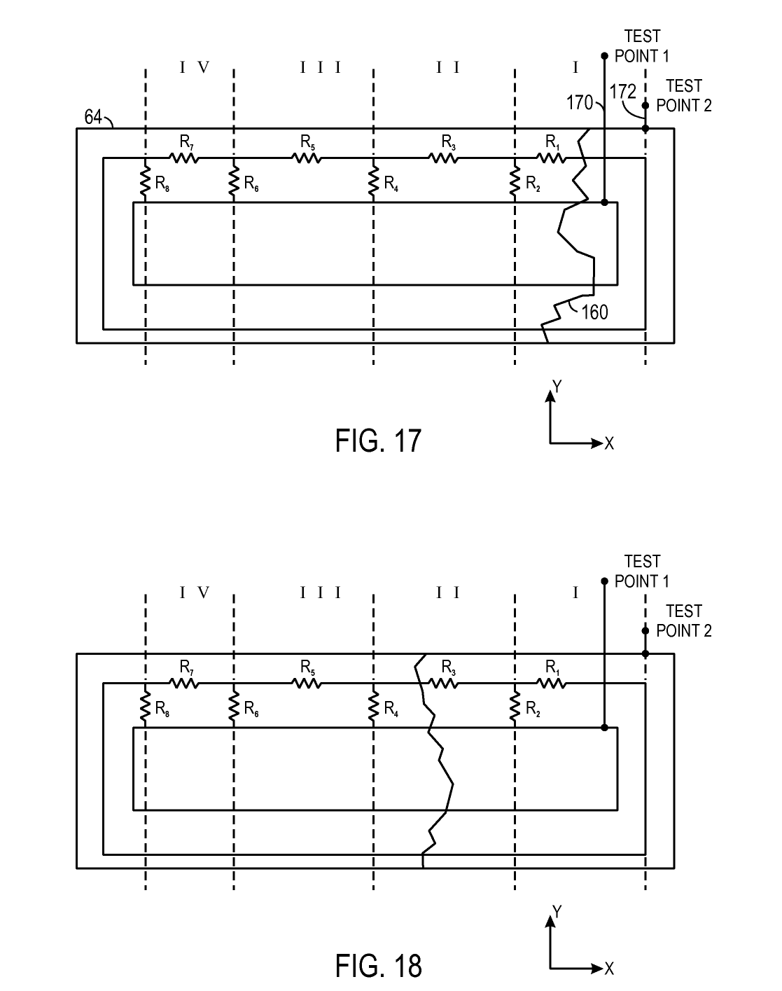

Specifically, when a fracture 160 occurs in region I of the display driver IC 64, as shown in FIG. 17, the resistance between the test points 170 and 172 may be exceptional high (e.g., a high-Z value). That is, there may be no resistive path through which the test points 170 and 172 may relate when the fracture 160 interrupts the resistive traces in the way shown in FIG. 17. When the fracture 160 occurs in region II, as shown in FIG. 18, the resistive path between the test points 170 and 172 flows through resistive elements R1 and R2. As such, a value of the test resistance Rₜₑₛₜ 176 that indicates a fracture has occurred in region II may be expected to be as follows:

Rₜₑₛₜ=R₁+R₂ (1).

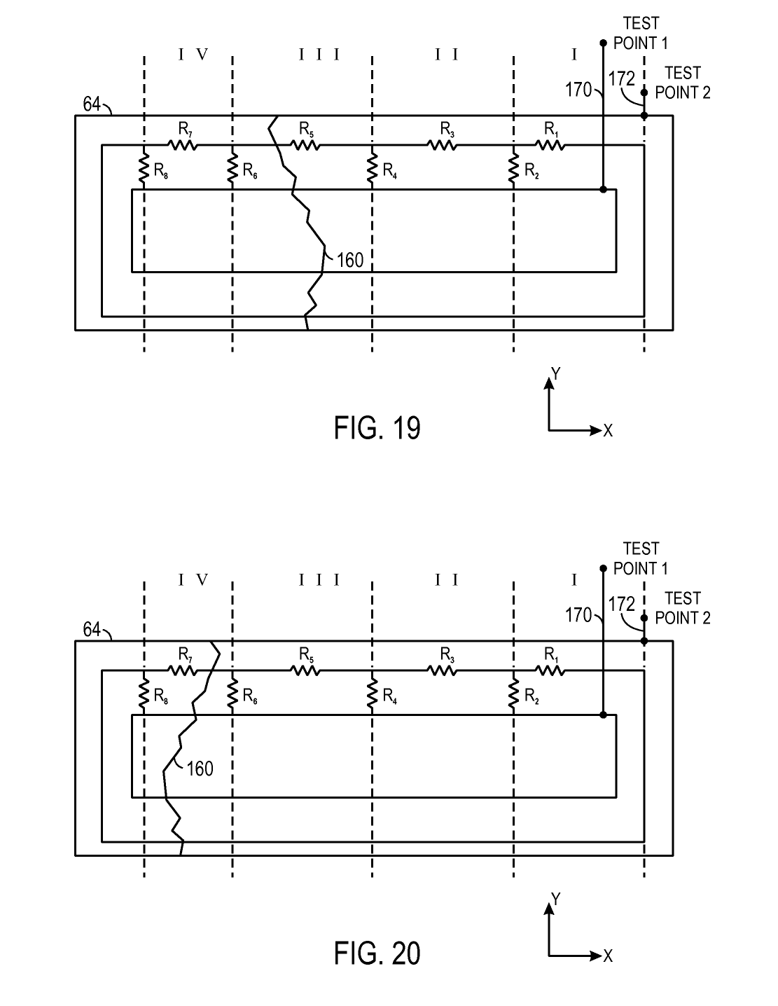

In an example shown in FIG. 19, a fracture 160 may occur in region III of the display driver IC 64. The resistance between the test points 170 and 172 may be reduced as additional resistive paths between them become available. Namely, the expected resistance when the fracture 160 occurs in region III may be expressed according to the following equation:

$${R}_{test} = \frac{{R}_{1} + {R}_{2} ( {R}_{3} + {R}_{4} )}{{R}_{2} + {R}_{3} + {R}_{4}} . \qquad ( 2 )$$

Finally, as shown in FIG. 20, a fracture 160 in region IV may open yet more resistive paths between the test points 170 and 172, lowering the total resistance between them even further. An expected test resistance Rₜₑₛₜ 176 between the test points 170 and 172 may be expressed according to the following equation:

$${R}_{test} = {R}_{1} + \frac{{R}_{2} ( {R}_{3} + \frac{{R}_{4} ( {R}_{5} + {R}_{6} )}{{R}_{4} + {R}_{5} + {R}_{6}} )}{{R}_{2} + {R}_{3} + \frac{{R}_{4} ( {R}_{5} + {R}_{6} )}{{R}_{4} + {R}_{5} + {R}_{6}}} . \qquad ( 3 )$$

As should be appreciated, additional regions may be defined accordingly to increase the precision of the identification of fractures 160 in the display driver IC 64.

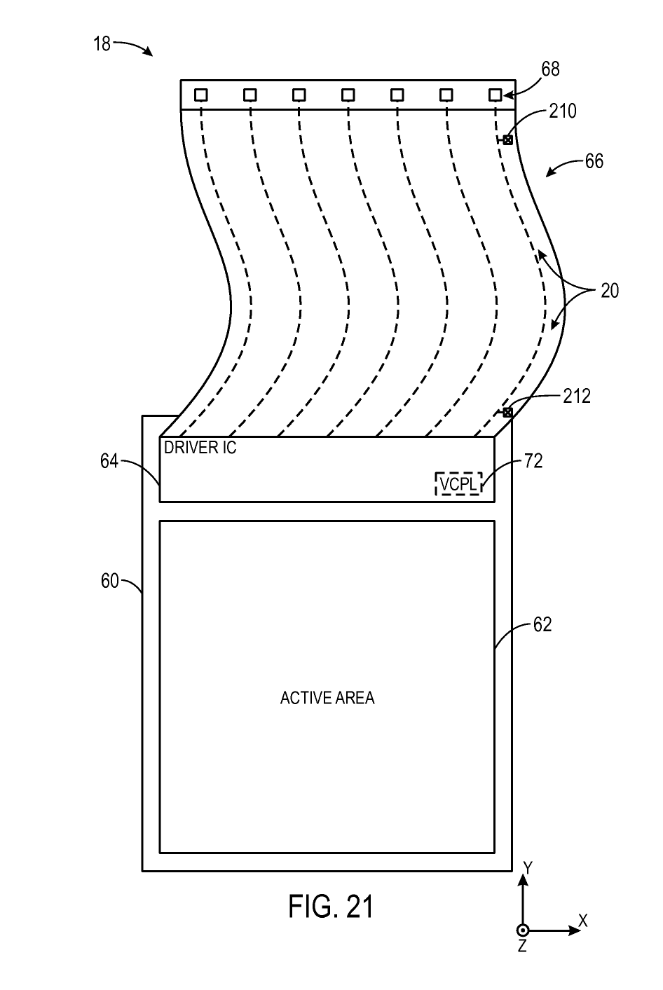

In other examples, the fracture detection circuitry 20 may be implemented in the flex 66 to identify fractures occurring before the display driver IC 64. In FIG. 21, the display 18 is shown to include the display panel 60, active area 62, and display driver IC 64 connected by flex 66 to flex connections 68. Disposed in the flex 66 may be test points 210 and 212 connecting to one of the interconnections 68 to the display driver IC 64. These test points 210 and 212 may represent an example of the display fracture detection circuitry 20 that can be used to determine when a fracture has occurred within the flex 66. As should be appreciated, by testing the resistance between the test points 210 and 212, the possibility of a fracture occurring in the flex 66 may be ruled out. A high-Z condition may indicate, for example, that a fracture is occurring somewhere within the flex 66. This may be used to rule out the likelihood of a fracture in the display driver IC 64.

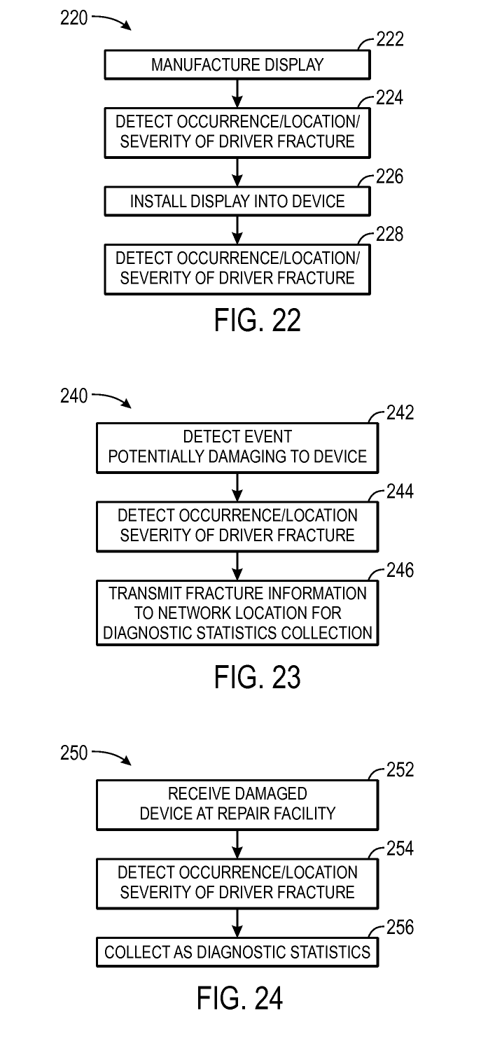

The various systems and techniques discussed above may be used in a variety of manners to improve the design and/or manufacturing process for electronic devices 10 that employ the display 18. As shown by a flowchart 220 of FIG. 22, for example, these systems and techniques may be used when a display 18 is manufactured (block 222). Using any of the above-described systems and methods, the occurrence, location, and/or severity of a fracture relating to the display driver IC 64 may be determined (block 224). Identifying a fracture at this point in the product lifecycle may identify potential points of failure during the manufacture of the display 18. Identifying fractures during manufacture may more easily identify a particular assembly line or vendor that may have processes that result in display fractures occurring at particular locations in the display driver IC 64 and/or flexible cabling 66 of the electronic displays 18 during the manufacture of the displays 18.

Additionally or alternatively, once the display 18 is installed into an electronic device 10 (block 226), the occurrence, location, and/or severity of a fracture relating to the display driver IC 64 may be detected according to the systems and techniques discussed above (block 228). Here, as above, detecting the occurrence, location, and/or severity of a fracture of the display driver IC 64 and/or the flexible cabling 66 may indicate a potential manufacturing or design flaw that is causing the display driver IC 64 and/or the flexible cabling 66 to fracture during the manufacture of the electronic device 10 into which the electronic display 18 is installed.

In a similar manner, the occurrence, location, and/or severity of a fracture relating to the display driver IC 64 may be determined after the display 18 has been manufactured, installed into an electronic device 10, and sold to customers. Two examples of when and how to start detecting the occurrence, location, and/or severity of fractures relating to the display driver IC 64 appear in FIGS. 23 and 24. In a flowchart 240 of FIG. 23, for example, an event that is potentially damaging to the display 18 and/or electronic device 10 may be detected (block 242). In one example, the motion sensor(s) 28 of may detect rapid motion. The rapid motion may indicate that the electronic device 10 has been dropped, an event that could damage the display 18. In another example, the temperature sensor 30 may detect a high or low temperature. Under these conditions, the temperature sensor 30 may indicate that the temperature of the display 18 and/or electronic device 10 is approaching a value that could damage the electronic device 10. In another example, another component of the electronic device 10 may fail. When the other component of the electronic device 10 fails, this may suggest the occurrence of an event that might also cause the display driver IC 64 to fail. In response to detecting the potentially damaging event at block 242, the electronic device 10 may detect whether a fracture has occurred in the display driver IC 64 using any of the systems or techniques discussed above (block 244). In this way, a fracture may be detected and determined to have occurred as a result of a particular event, which may be recorded in the electronic device 10 (e.g., in the storage 16) or transmitted to a network location for diagnostic statistics collection (e.g., a database at an Internet location) (block 246). When the electronic device 10 stores this fracture information without transmitting it, the fracture information may be later accessed, for example, if the electronic device 10 is subsequently brought to a customer support facility.

In one example, as illustrated by a flowchart 250 of FIG. 24, a consumer may bring a damaged electronic device 10 to a repair or customer support facility (e.g., a Genius Bar® at an Apple Store®) (block 252). To identify whether the failure of the electronic device 10 is due in part to a fracture in the display driver IC 64, the repair or customer support facility may detect the occurrence, location, and/or severity of such a fracture (block 254). For example, the repair or customer support facility may download the fracture information from the electronic device 10 if the fracture information is stored on the electronic device 10. Additionally or alternatively, the repair or customer support facility may perform any of the techniques discussed above to determine the occurrence, location, and/or severity of a fracture of an integrated circuit (e.g., display driver IC 64) of the electronic device 10. Identifying whether the occurrence, location, and/or severity of a fracture within the electronic device 10 may enable the repair or customer support facility to follow an appropriate course of repair. In addition, however, the fracture information may be collected and stored as diagnostic statistics associated with the fracture of the integrated circuit (e.g., the display driver IC 64) (block 256). The repair or customer support facility may send such diagnostic statistics to the network location mentioned above (e.g., to a database on the Internet or a private network). Whether obtained directly from the electronic device 10 or via a repair or customer support facility, statistics relating to the occurrence, location, and/or severity of fractures in an integrated circuit of the electronic device 10 may be used to improve the design and/or manufacture of the electronic device 10.

The specific embodiments described above have been shown by way of example, and it should be understood that these embodiments may be susceptible to various modifications and alternative forms. Indeed, the fracture detection circuitry and techniques discussed above may be used to ascertain fractures in silicon in many different devices not subject to external observation. For example, the fracture detection circuitry and/or techniques may be used to detect fractures in silicon integrated circuits that are covered by shield cans meant to reduce electromagnetic interference (EMI) or that are covered by large heat sinks. Such shield cans and heat sinks may be found in printed circuit boards in many electronic devices. Using the techniques discussed above, fractures in the integrated circuits covered by shield cans and/or heat sinks may be detected even though these integrated circuits may be hidden from external observation. It should be further understood that the claims are not intended to be limited to the particular forms disclosed, but rather to cover all modifications, equivalents, and alternatives falling within the spirit and scope of this disclosure.

What is claimed is:

1. A method comprising:
obtaining a measurement of a property of an integrated circuit through at least one contact of the integrated circuit, wherein the measurement comprises a measurement of a resistance of a resistive pattern in the integrated circuit or a measurement of current-voltage behavior of a power supply of the integrated circuit;
comparing the measurement of the property to an expected baseline property; and
determining whether a fracture of the integrated circuit has occurred and a location of the fracture in the integrated circuit based at least in part on the comparison.

2. The method of claim 1, wherein:
the measurement of the property comprises the measurement of the resistance of the resistive pattern in the integrated circuit;
the expected baseline property comprises a resistance that is expected when the resistive pattern is not interrupted by the fracture; and
the fracture is determined to have occurred when the resistance of the resistive pattern in the integrated circuit substantially does not match the resistance that is expected when the resistive pattern is not interrupted by the fracture.

3. The method of claim 1, comprising, when the fracture has been determined to have occurred, determining a region of the integrated circuit where the fracture has occurred based at least in part on a difference between the measurement of the resistance of the resistive pattern in the integrated circuit and the resistance that is expected when the resistive pattern is not interrupted by the fracture.

4. The method of claim 1, wherein:
the measurement of the property comprises the measurement of current-voltage behavior;
the expected baseline property comprises an expected baseline current-voltage behavior; and
the fracture is determined to have occurred when the measurement of current-voltage behavior substantially does not match the expected baseline current-voltage behavior.

5. The method of claim 1, comprising, when the fracture is determined to have occurred, determining a region of the integrated circuit where the fracture has occurred based at least in part on which power supply is measured to have the measurement of current-voltage behavior that substantially does not match the expected baseline current-voltage behavior.

6. The method of claim 1, comprising, when the fracture has occurred, determining a region of the integrated circuit where the fracture has occurred based at least in part on the comparison.

7. One or more articles of manufacture comprising a non-transitory machine-readable media storing instructions to:
(a) receive a measurement of a behavior of a component of a display driver of an electronic display of an electronic device; and
(b) determine a location of a fracture in the display driver when the fracture has occurred based at least in part on the measurement of the behavior.

8. The one or more articles of manufacture of claim 7, comprising instructions to perform instructions (a) and (b) when a potentially damaging event occurs in the electronic device.

9. The one or more articles of manufacture of claim 8, comprising instructions to identify an indication of rapid motion from a motion sensor as the occurrence of the potentially damaging event.

10. The one or more articles of manufacture of claim 8, comprising instructions to identify an indication of a temperature measurement from a temperature sensor that falls outside a threshold range as the occurrence of the potentially damaging event.

11. The one or more articles of manufacture of claim 8, comprising instructions to identify that another component of the electronic device has failed to represent the occurrence of the potentially damaging event.

12. The one or more articles of manufacture of claim 7, comprising instructions to store an indication of the location of the fracture on storage of the electronic device or send the indication of the location of the fracture to a network location, or both.

13. An electronic device comprising:
a processor configured to generate image data; and
an electronic display configured to display the image data, wherein the electronic display comprises:
a display panel;
display driver circuitry configured to program the image data on the display panel, wherein the display driver circuitry comprises a first component whose behavior is configured to vary based at least in part on whether a fracture has occurred in the display driver circuitry; and
measurement circuitry configured to perform a measurement of the behavior of the first component of the display driver circuitry;
wherein the processor or the electronic display comprises fracture analysis logic configured to configured to determine, based at least in part on the measurement of the behavior of the first component of the display driver circuitry:
whether the fracture has occurred; and
when the fracture has occurred, a region of the display driver circuitry where the fracture has occurred.

14. The electronic device of claim 13, wherein the first component of the display driver circuitry comprises a resistive pattern configured to be measured to have a different resistive behavior when the fracture occurs in different regions of the display driver circuitry.

15. The electronic device of claim 13, wherein the first component of the display driver circuitry comprises a resistive pattern configured to be measured from two test points disposed in a first region, wherein the resistive behavior measured between the two test points is configured to be a highest resistance when the fracture occurs in the first region and to be progressively lower resistances at regions farther from the first region.

16. The electronic device of claim 13, wherein the first component of the display driver circuitry comprises a plurality of power supply connections, wherein each of the power supply connections has a respective spatial relationship to a voltage controlled positive inductance (VCPL) backplane, and wherein measured current-voltage behaviors of the plurality of power supply connections are configured to vary from respective baseline current-voltage behaviors when a fracture has occurred that occurs between the power supply connection and the VCPL backplane.

17. The electronic device of claim 13, wherein the fracture analysis logic comprises instructions executed by the processor of the electronic device.

18. The electronic device of claim 13, wherein the fracture analysis logic comprises instructions executed by a microcontroller of the electronic display.

19. The electronic device of claim 13, wherein the fracture analysis logic comprises an application specific integrated circuit of the electronic display.

20. The electronic device of claim 13, wherein the electronic device comprises a desktop computer, a notebook computer, a tablet computer, a handheld device, a portable media device, a cellular phone, or any combination thereof.

21. A method comprising:
measuring current-voltage behavior of a plurality of power supply connections of an integrated circuit;
comparing the measured current-voltage behavior of the plurality of power supply connections to respective baseline current-voltage behavior of the plurality of power supply connections; and
identifying whether a fracture has occurred in the integrated circuit based at least in part on the comparison.

22. The method of claim 21, wherein the fracture is identified as having occurred in the integrated circuit when the measured current-voltage behavior of at least one of the plurality of power supply connections does not substantially match the respective baseline current-voltage behavior of the at least one of the plurality of power supply connections.

23. The method of claim 21, comprising, when the fracture is identified as having occurred in the integrated circuit, identifying a region within the integrated circuit where the fracture has occurred based at least in part on which of the measured current-voltage behavior of the plurality of power supply connections differs from the respective baseline current-voltage behavior of the plurality of power supply connections.

24. The method of claim 21, wherein the measured current-voltage behavior is a relationship between the plurality of power supply connections and a voltage controlled positive inductance (VCPL) backplane of the integrated circuit.

25. The method of claim 24, wherein each power supply connection relates to the VCPL backplane through a respective p-n junction, wherein the measured current-voltage behavior of the p-n junction is configured to differ from its respective baseline current-voltage behavior at least when a fracture crosses the p-n junction.

26. The method of claim 21, wherein the integrated circuit comprises a component of an electronic device, wherein the component is installed so as to be inaccessible to external inspection.

27. The method of claim 21, wherein the integrated circuit comprises a display driver.

28. The method of claim 21, wherein the integrated circuit is hidden from external observation by a shield can or a heat sink, or both.

29. A method comprising:
providing an electronic display, wherein the electronic display comprises display driver circuitry inaccessible to external inspection;
measuring a behavior of the display driver circuitry to obtain a first measurement of the behavior of the display driver circuitry;
detecting whether a fracture has occurred in the display driver circuitry based at least in part on the first measurement of the behavior of the display driver circuitry; and
when the fracture is detected to have occurred in the display driver circuitry, detecting a region of the display driver circuitry where the fracture has occurred based at least in part on the first measurement of the behavior of the display driver circuitry.

30. The method of claim 29, wherein measuring the behavior of the display driver circuitry comprises to obtain the first measurement comprises measuring a current-voltage behavior of each of a plurality of power supply connections of the display driver circuitry, and wherein detecting the region of the fracture occurring in the display driver circuitry comprises comparing the measured current-voltage behavior of each of the plurality of power supply connections to respective expected baseline current-voltage behavior.

31. The method of claim 29, wherein measuring the behavior of the display driver circuitry to obtain the first measurement comprises measuring a resistance of a resistive pattern of the display driver circuitry, and wherein detecting the region of the fracture occurring in the display driver circuitry comprises comparing the measured resistance to resistances expected when the fracture occurs in different regions in the display driver circuitry.

32. The method of claim 29, comprising, when the fracture is not detected to have occurred based at least in part on the first measurement, installing the electronic display into an electronic device.

33. The method of claim 32, comprising, after the electronic display has been installed into the electronic device:
measuring the behavior of the display driver circuitry to obtain a second measurement of the behavior of the display driver circuitry;
detecting whether the fracture has occurred in the display driver circuitry based at least in part on the second measurement of the behavior of the display driver circuitry; and
when the fracture is detected to have occurred in the display driver circuitry, detecting the region of the display driver circuitry where the fracture has occurred based at least in part on the second measurement of the behavior of the display driver circuitry.

34. The method of claim 29, wherein measuring the behavior of the display driver circuitry comprises measuring a resistance of a flexible printed circuit that provides connections to the display driver circuitry.
